(19) United States
(12) Patent Application Publication
(10) Pub. No.: US 2004/0050493 A1
(43) Pub. Date: Mar. 18, 2004

(54) Method and an apparatus for excitation of a plasma

(76) Inventor: Bjorn Winther-Jensen, Bronshoj (DK)

Correspondence Address: FINNEGAN, HENDERSON, FARABOW, GARRETT & DUNNER, LLP, 1300 I STREET, NW, WASHINGTON, DC, 20005, US

(21) Appl. No.: 10/415,140

(22) PCT Filed: Oct. 27, 2001
(86) PCT No.: PCT/DK01/00714

(30) Foreign Application Priority Data
Oct. 27, 2000 (DK) PA 2000 01609

(51) Int. Cl. C23F 1/00; C03C 15/00; H01L 21/306

(52) U.S. Cl. 156/345.35; 427/446; 216/68

(57) ABSTRACT

A method of exciting a plasma, wherein a gas is subjected to an electrical field generated by means of a plurality of electrodes. One electrode is formed by an outer metal pipe (1). This outer metal pipe (1) surrounds one or more inner metal pipes (2) which form the other electrode. The idea is to turn it to account that plasma is generated in one or more of the inner pipes. These pipes are easier to clean, and the cleaning process is therefore simplified considerably. To this should be added that the distance between the electrodes may now be increased considerably, thereby reducing the risk of breakdown between the electrodes.

The invention relates to a method of exciting a plasma, wherein a gas is subjected to an electrical field generated by means of an electrode system consisting of several electrodes.

An apparatus comprising such an electrode system for generating a plasma is known e.g. from PA 1999 0067. The electrode system described therein consists of a large number of electrodes. However, a drawback is that the electrodes are contaminated by the material which is passed through the plasma during a plasma treatment. These electrodes must therefore be removed and cleaned at regular intervals and perhaps be exchanged. This is cumbersome and adds to the costs.

The objective of the invention is to provide a method and an apparatus for excitation of a plasma wherein this cleaning process is considerably easier to perform.

This and other objects have been achieved by the invention as it is defined in the claims.

In general, the apparatus for excitation of a plasma, comprising a container in which a gas may be subjected to an electrical field generated by means of an electrode system consisting of several electrode where in one electrode is formed by an outer pipe which surrounds one or more inner pipes, said inner pipe forming one or more of the other electrodes.

These pipes are easier to clean, and the cleaning process is hereby simplified considerably. To this should be added that the distance between the electrodes may now be increased, typically by a factor 10, thereby reducing the risk of breakdown between the electrodes.

The apparatus according to the invention comprising a plasma treating chamber in which a gas may be subjected to an electrical field generated by means of an electrode system. The electrode system comprise two or more electrodes including a first outer pipe shaped electrode and an innermost pipe shaped electrode wherein the innermost electrode surrounds the plasma treating chamber.

The outer pipe shaped electrode surrounds the inner most pipe shaped electrode in at least a part of its pipe height, wherein the pipe height is the distance from one end of the pipe to the other end.

A pipe shaped electrode is as the term indicate formed as a pipe, with a round going pipe wall, wherein the pipe or pipe wall may have any cross sectional shape. The pipe height is the smallest distance from the ends of the pipe wall measured in a direction parallel to the centre line of the pipe, wherein the centre line is the most central line through the pipe.

The electrode system may comprise two or more pipe shaped inner electrodes, wherein at least one of these inner electrodes being the innermost electrode. The other inner electrodes being denoted the additional inner electrodes.

In the apparatus according to the invention the innermost electrode may be surrounded by the one or more additional inner electrode, which in turn is surrounded by the outer electrode. By using such additional inner electrodes a more uniform plasma may be generated.

It should be observed that a plasma between the electrodes may be obtained as well. This plasma does, however, in general not become as homogeneously as the plasma generated in the plasma treating chamber. Furthermore the distance between the electrodes may be rather small e.g. down to 5 or 10 mm and thereby there will only be room for treating substrates of very specific shapes and size. The distance between the electrodes may be increased depending on the size of the power supply e.g. up to 5 or 10 cm.

In order to avoid the creation of sparks between the electrodes and simultaneously having a short distance between the electrodes an insulating material may be placed between the electrodes. The insulating material may preferably be shaped as a pipe as well, and have a pipe height which is as least as height as the pipe height of the electrode with the second most heighest pipe height. Furthermore the pipe shaped elements should preferably be adjusted relative to each other so that the insulating material uptakes as much of the distance area between the electrode with the second most heighest pipe height and the electrode with the most heighest pipe height.

The insulating material may in principle be of any type such as glass, ceramic or a polymeric material including rubber and thermoplastic, such as polyethylene (PE), polyvinylchloride (PVC), polyamide polyvinyldifluoride (PVDF) and carbon-filled polyethylene.

It is preferred that the outer electrode is surrounded or coated with an insulating material. This insulating material may preferably cover the total outermost surface of the outer electrode. The insulating material may be as described above,

The pipe shaped electrodes may comprise several through going openings in the pipe wall. In principle at least up to about 95% of the pipe wall area of a pipe shaped electrode may be through going openings. In one embodiment it is preferred that up to about 60%, such as between 25 and 50% of the pipe wall area of a pipe shaped electrode is in the form of through going openings. The through going openings may be in the form of a mesh, such as a mesh having opening corresponding to a mesh size of between 0.01-20 mm, preferably between 0.1 and 10 mm. As it will be shown below the use of a pipe shaped electrode with through going openings as explained above, particular in situation where this electrode in the innermost electrode, may result in an even more homogeneously generated plasma in the plasma treating chamber.

As mentioned the electrodes may in principle have a cross section with any shape, also donated a round going shape even though it need not be round but may be angular as well. In order to obtain an apparatus with a plasma treating chamber which is particular easy to clean it is preferred that the inner surface of the innermost electrode is substantially free of nooks and crannys.

It should also be observed that the cross section need not be of the same shape in the whole of the pipe height of an electrode. However, in most situations an electrode has a substantially identical cross in the whole of the pipe height of an electrode.

The electrodes of an electrode system may have different geometrical shape including different cross section.

In one embodiment it is preferred that at least one and preferably both of the outer electrode and the innermost electrode and optionally any additional inner electrodes having a substantially circular cross-section. The or these electrodes may have a substantially circular cross-section in the whole pipe length of the electrodes, to there by have a substantially cylindrical shape.

In another embodiment the outer electrode has a polygonal shape, such as a rectangular shape, In this embodiment the one or more inner electrodes may have an elliptic shaped cross-section.

The electrode system may comprise two or more innermost electrode. Is situation where the system comprise two or more innermost electrodes, these innermost electrodes optionally individually surrounded with other inner electrodes are placed beside each other and surrounded with the outer electrode. Each of the innermost electrodes surrounds a plasma treating chamber.

In most situations an innermost electrode do not surround any further electrodes. An innermost electrode may, however, surround a further electrode, which is not a part of the plasma generating electrode system, but is an additional electrode such as a sputtering electrode.

Thus, according to one embodiment the apparatus of the invention further comprise a sputtering electrode e.g. made of tin, copper, silver, gold, platinum or aluminium, which sputtering electrode preferably is placed in the plasma treating chamber. The sputtering electrode may be of any type such as it is generally known in the art e.g. as described in WO 00/44207 which is hereby incorporated by reference.

The electrode may be of any kind of suitable material, e.g. metals such as steel. Furthermore one or more of the electrodes may be made of or coated with a poorly conducting material, such as carbon-filled polymer e.g. carbon-filled polyethylene.

As it is generally known from prior art plasma generating apparatus, the apparatus of the invention comprise means for providing a vacuum in the plasma treating chamber, e.g. in the form of an integrated vacuum pump or means for connecting the apparatus to a vacuum pump. Further the apparatus comprises an inlet for introducing the gas into the plasma treating chamber.

The apparatus according to the invention may further comprise a holder for holding a substrate to be plasma treated i.e. in the form of a support plate. The holder should naturally be placed in the plasma treating chamber.

The apparatus further comprise an apparatus according means for being connected to a power source, preferably selected from the group consisting of an alternating current (AC), a direct current (DC), low frequency (LF), audio frequency (AF), radio frequency (RE) and microwave power source e.g. as described in EP 831 679 or WO 00/44207 which is hereby incorporated by reference.

In general the method of exciting a plasma, wherein a gas is subjected to an electrical field generated by means of an electrode system consisting of several electrodes, is characterised by that one electrode is formed by an outer pipe which surrounds one or more inner pipes said inner pipes forming the one or the other electrodes, turning to account that a plasma is generated in one or more of the inner pipes.

The method according the invention of exciting a plasma in a plasma treating chamber, wherein a gas is subjected to an electrical field generated by means of an apparatus as described above and defined in the claims comprise the steps of introducing the gas into said plasma treating chamber and applying a power source to said electrodes to thereby generate a plasma in the plasma treating chamber.

As it is generally known the plasma treating chamber should initially be totally or partly evacuated e.g. by use of a vacuum pump. Hereafter a further treatment gas may preferably be introduced. The gas may be e.g. be as described in PCT/DK01/00327 or EP 346 005 which is hereby incorporated by reference.

The power source is applied e.g. an alternating current (AC), a direct current (DC), low frequency (LF), audio frequency (AS), radio frequency (RF) and microwave power source. Further information concerning the application of power source can be found in EP 831 679 or WO 00/44207.

The pressure in the plasma treating chamber may preferably be adjusted to less than 1 mbar, preferably to less than 0.4 mbar during the generation of plasma. The optimal pressure for providing a plasma treatment depends on the kind of treatment. Further information concerning the treatment pressure may be found in PCT/DK01/00327 or EP 346 005.

The substrate to be treated is preferably placed in the plasma treating chamber prior to the generation of the plasma.

The substrate to be treated may in principle be of any type of solid material such as any type of polymeric materials, silicon dioxide ceramic, glass, and carbon e.t.c.

Furthermore the substrate may have any shape including fibres.

The invention shall now be explained in further details with reference to the drawings. The drawings are only meant to illustrate specific embodiments of the invention and should not in any way be considered to be a limitation of the scope of the invention, as the skilled person would be able to carry out the invention in may other ways.

The invention will be explained more fully below with reference to the drawing, in which

FIG. 1 shows a cross-section of a known apparatus for excitation of a plasma,

FIG. 2 shows a cross-section of an apparatus according to the invention for excitation of a plasma,

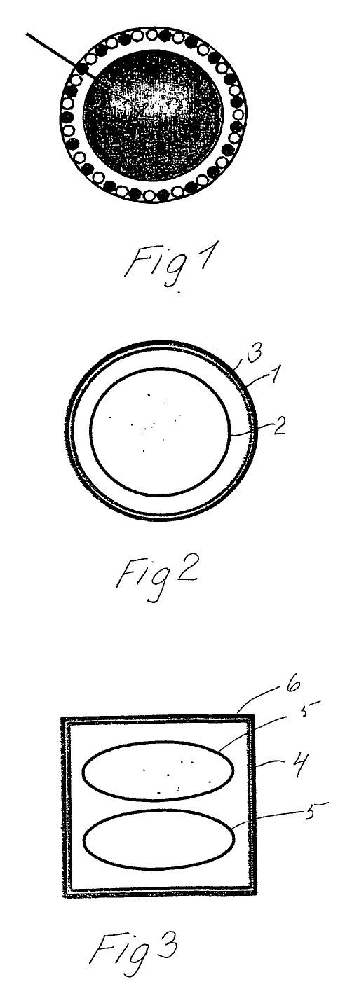

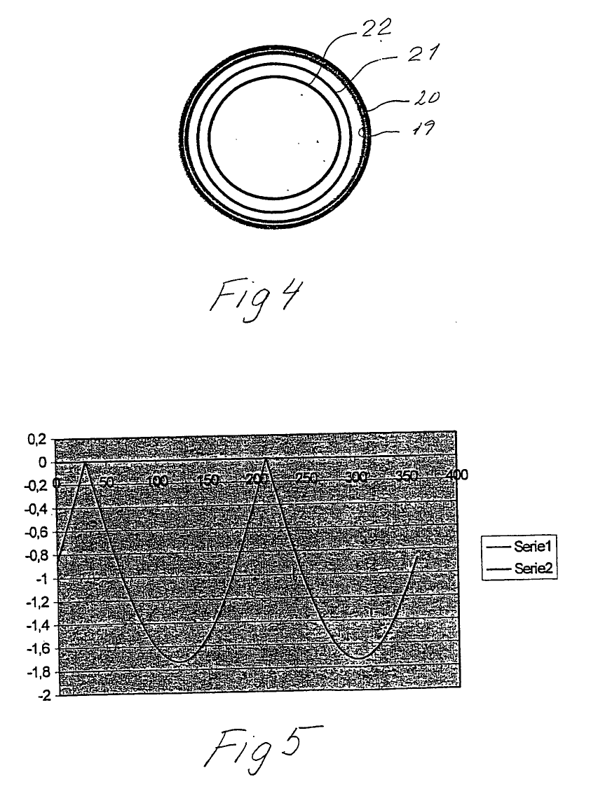

FIG. 3 shows the apparatus in an embodiment using two phases of the network,

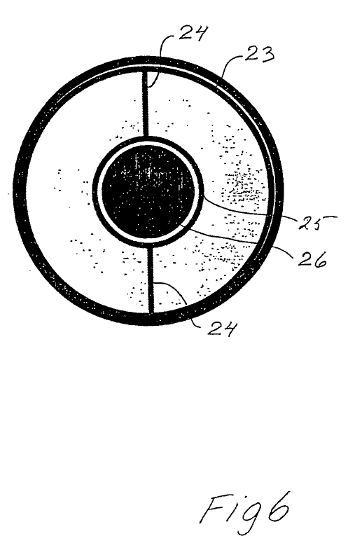

FIG. 4 shows the apparatus in an embodiment using three phases of the network,

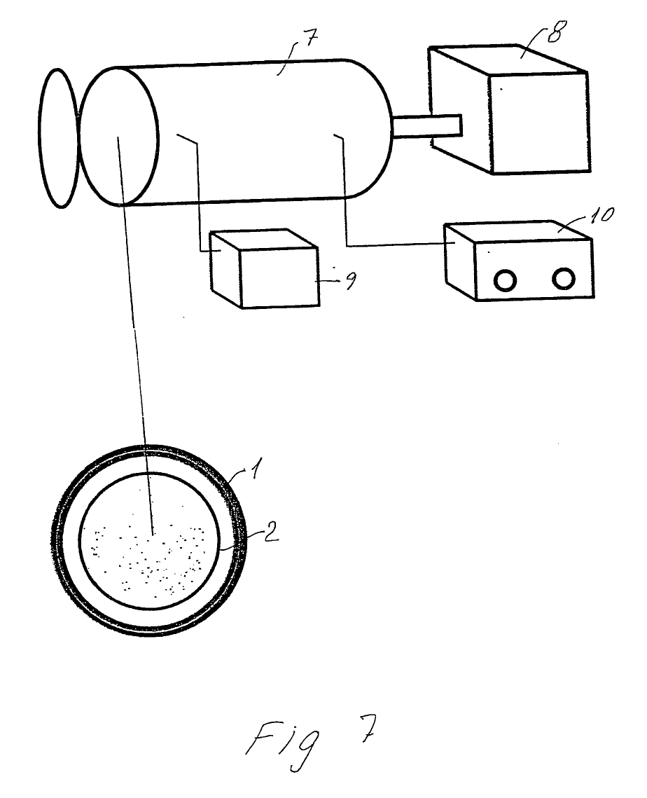

FIG. 5 is an illustration of the voltage conditions in 2-phase power supplies like in FIGS. 7-9,

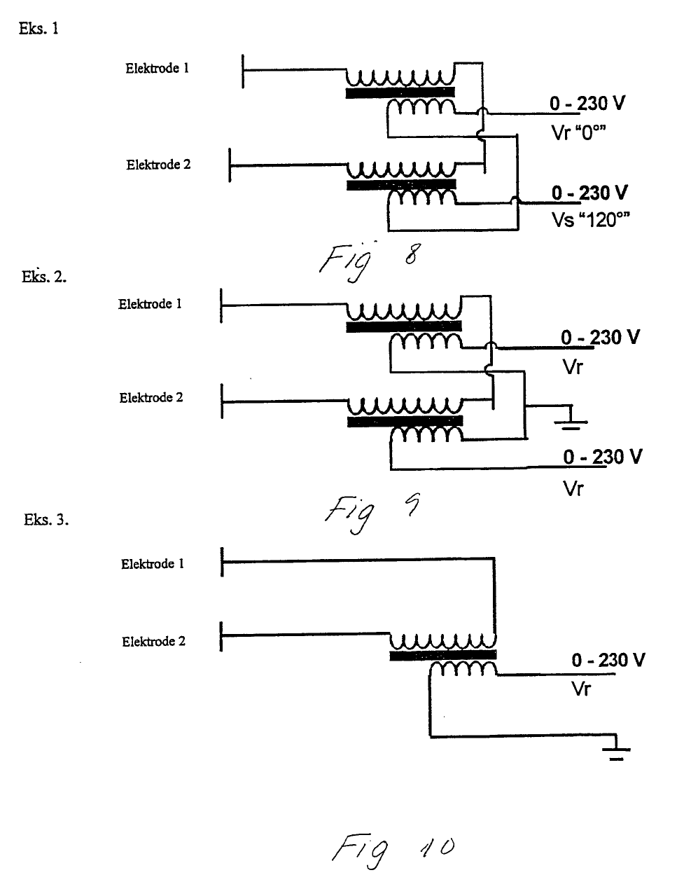

FIG. 6 shows the apparatus in another embodiment,

FIG. 7 shows the entire system for excitation of a plasma,

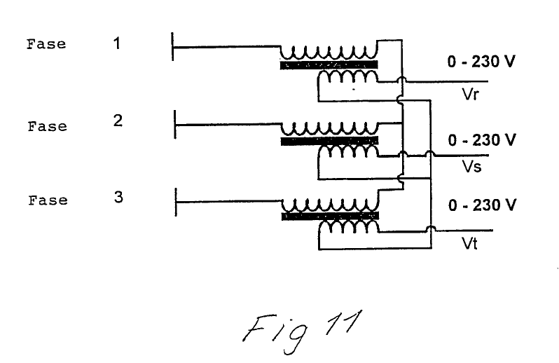

FIGS. 8-11 show examples of power supplies to the system,

FIG. 12 shows an example of a suspension for the inner electrode in connection with the embodiment shown in FIG. 2,

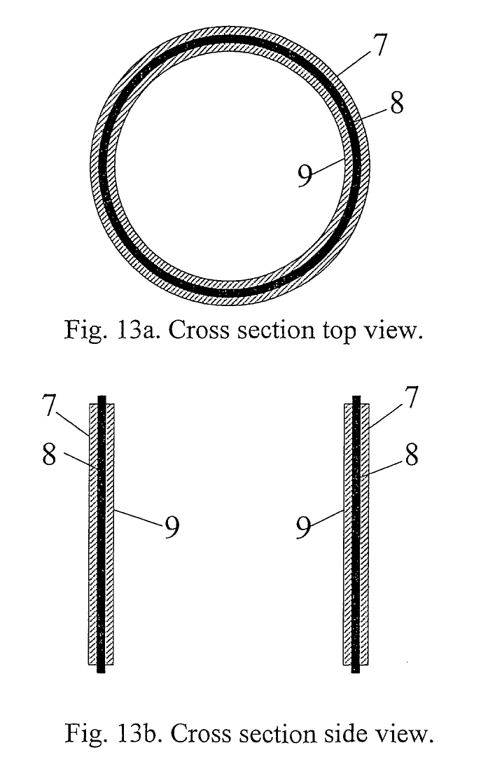

FIGS. 13a and 13b shows the apparatus in another embodiment using two phases of the network,

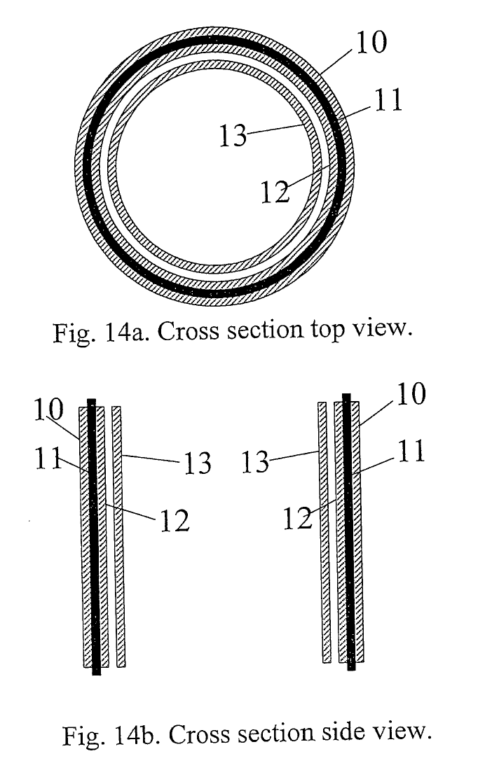

FIGS. 14a and 14b shows the apparatus in another embodiment using two phases of the network,

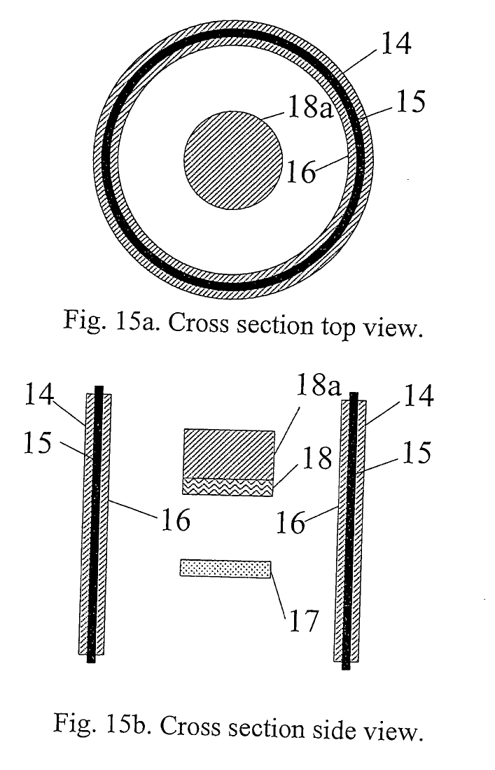

FIGS. 15a and 15b shows the apparatus in another embodiment using three phases of the network,

FIG. 1 describes a prior art apparatus as it is described in the introduction of the application.

The apparatus according to the invention shown in FIG. 2 for excitation of a gas, such as argon, for a plasma consists of at least two electrodes 1, 2. The electrodes 1, 2, are configured as pipes, innermost pipe shaped electrode 2 being arranged inside the outer pipe shaped electrode 1 in vacuum applied to said gas at a pressure of e.g. 0.01-1.0 mbar. By applying phase 1 and phase 2, respectively, of the network to the two electrodes—see FIG. 7—diffusion plasma is formed a plasma treating chamber surrounded by the innermost pipe shaped electrode 2.

It can be observed that the plasma is formed in reality, but it cannot be explained scientifically why. The object or substrate to be plasma-treated is then introduced into the cavity or plasma treating chamber in which the plasma is formed. The substrate may e.g. be strips of plastics, which are to be surface-treated to achieve special surface properties.

The outer cylindrical electrode 1 is surrounded by an insulating layer 3. A special advantage of this electrode structure is that it is particularly easy to clean. Such a cleaning is necessary, since, otherwise, the electrode might be contaminated to such a degree that sparking might take place. Such sparking should be avoided, of course. To this should be added that the distance between the electrodes may now be increased, thereby reducing the risk of sparking additionally.

In another embodiment, which is shown in FIGS. 13a and 13b, the electrodes 7, 9, are configured as pipes and connected to the two phases, respectively, of the network as described in above for FIG. 2. In this case, however, the electrodes are separated by an electrically insulating material 8, e.g. glass, ceramic, or polymer, e.g. polyethylene (PE), polyvinylchloride (PVC), polyamide (PA), polyvinyldifluoride (PVDF).

The advantage of this configuration over the configuration described in above and shown in, FIG. 2 is the fact that the appearance of sparks between the electrodes is dramatically reduced allowing for a higher applied voltage difference between the electrodes and hence a higher power throughput in the plasma. It should be observed that the minimum voltage difference at which a plasma can be sustained is higher for this configuration shown in FIGS. 13 and 13b as compared to the configuration shown in FIG. 2.

In another embodiment, which is shown in FIGS. 14a and 14b, the two configurations shown in FIGS. 2 and 13a/13b, respectively, are combined. When high power througput (aggressive plasma) is required a high voltage difference is applied to the electrodes 10, 12, which are separated by an electrically insulating material 8 as described above describing FIGS. 13a/13b. When low power throughput (gentle plasma) is required a lower voltage difference is applied to the electrodes 12 and 13, as described above when describing FIG. 2.

In another embodiment, which is shown in FIGS. 15a and 15B, the configuration described shown in FIGS. 13a/13b is supplemented with a sputtering electrode 17, made of e.g. tin, copper, silver, gold, platinum, aluminium. The electrodes 14, 16, 18, are connected to each of the three phases of the power grid. The sputtering is directed towards the substrate to be coated with the use of a magnet 18a.

In another embodiment, which is shown in FIG. 3, the outer electrode consists of a cross-sectionally square electrode 4, while the innermost electrodes is formed by two cross-sectionally elliptic electrodes 5.

The outer square electrode is connected to one phase of the network, while the innermost electrodes 5 are connected to another phase of the network. In this case, too, the outer electrode 4 is surrounded by an insulation 6.

In case of a two-phase system where one phase is shifted 120° relative to the other and the vacuum container is connected to 0 (earth), and the rear sides of the transformers through which the various phases are fed are interconnected, special and desirable properties in the plasma are achieved. The voltage course is as outlined in FIG. 5. That is a pulsed plasma with a frequency of 100 Hz. A change in the phase shift between the two phases will only affect the voltage level, as a minor phase difference gives a minor voltage difference.

In another embodiment, which is shown in FIG. 4, the apparatus contains three electrodes, viz. a first outer electrode 19 comprising an insulation layer 20, an inner electrode 21 in the form of a cylindrical electrode arranged inside the outer cylindrical electrode 19, and an innermost electrode 22 in the form of a cylindrical electrode arranged inside the inner cylindrical electrode 21. The plasma treating chamber is constituted by the cavity of the innermost electrode. Phase 1, phase 2 and phase 3, respectively, of the three-phase network are fed to the three electrodes (via a three-phase transformer, cf. FIG. 11). Plasma is generated in all the cavities in the operation of this apparatus. The plasma generated in the plasma treating chamber is the most homogeneous one, and this is what is utilized.

The advantage of this apparatus which is driven by means of three phases, is that a greater energy density and a more even energy course are achieved.

FIG. 6 shows an alternative electrode configuration for a 2-phase plasma system consisting of an outer circular solid electrode 23, which is connected via two radial and diametrically oppositely arranged mesh-shaped flaps 24 with an innermost cylindrical electrode 25, which is likewise mesh-shaped. The inner mesh-shaped electrode 25 has arranged therein an electrode, which may be a solid rod-shaped electrode, but which may simultaneously constitute a substrate holder 26. The plasma is formed in the cavities of the first electrode 23, 24, as well as in the plasma treating chamber.

The advantage of this electrode configuration is that it makes it possible to tumble small objects or fillers in the cavities of the first electrode, as well as in the plasma treating chamber. The electrodes may advantageously be made of or be coated with a poorly conducting material, such as carbon-filled polyethylene, since sparking on the electrodes may be suppressed hereby.

FIG. 7 shows the entire system, illustrating the vacuum chamber 37 in which the electrodes 1, 2 are arranged, and a vacuum pump 38 connected with the vacuum chamber 37. The vacuum chamber 37 also has connected thereto a gas supply 39 for the supply of the gas which is to be excited for the generation of a plasma in the vacuum chamber 37. The fed gas may e.g. be argon or atmospheric air. Also shown is a power supply 40, from which two phases are fed to the electrodes 1, 2 inside the vacuum chamber 37. Also shown is a sectional view of the vacuum chamber 37 with the two inner electrodes 1, 2 corresponding to the embodiment in FIG. 2.

The suspension of the inner electrode 2 may advantageously take place with a thermally stable and insulating material, which withstands a temperature of about 200° C. The material may e.g. be PTFE or a ceramic material.

FIG. 12 shows an example of a suspension, illustrating the attachment of an inner electrode 52 into which a holder 55 for the substrate 54 to be treated may be introduced. An outer electrode 51 has the shape of a pipe, which is arranged in a tubular insulating material, which is in turn arranged in a vacuum chamber. The innermost electrode 52 consists of a tubular mesh of stainless steel.

Some longitudinally extending, radially arranged flaps 56 of insulating materials, such as PTFE, are secured to the outer electrode 51 and carry the innermost electrode 52 together with the substrate holder 55 which may be arranged inside the inner electrode 52. The substrate holder 55 is in several tiers and is secured to the inwardly extending flaps 56 by means of carrier rails 57, so that the substrate holder 55 may be displaced in the longitudinal direction for removal or introduction of substrates 54 to be plasma-treated. The lengths (also denoted the pipe heights) and positions of the electrodes 51, 52 relative to each other may be varied. The innermost electrode 52 may optionally be shorter than the outer one. The homogeneity of the plasma may vary however. The mesh-shaped electrode 52 causes the plasma to be more homogeneous.

FIGS. 8-11 show examples of power supplies to the apparatuses shown in FIGS. 2, 3 and 4, respectively.

The voltage supply shown in FIG. 8, which is intended to drive the apparatuses shown in FIGS. 2 and 3, utilizes two phases (r and s) from a three-phase network. The two phases are shifted 120° relative to each other. The input voltages Vr and Vs are transformed by means of transformers to the desired voltage for the plasma chamber. The rear sides of the two transformers are interconnected.

The voltage supply shown in FIG. 9, which is likewise intended to drive the apparatuses shown in FIGS. 2 and 3, utilizes one phase (r) from a three-phase network. Two transformers, one for electrode 1 and one for electrode 2, are used for transforming the voltage to the desired voltage for the plasma chamber. The transformer for electrode 2 is connected so that a phase shift of phases (r) of 180° takes place such that there is a phase difference of 180° between electrode 1 and electrode 2. The rear sides of the two transformers are connected to each other each and to “0”.

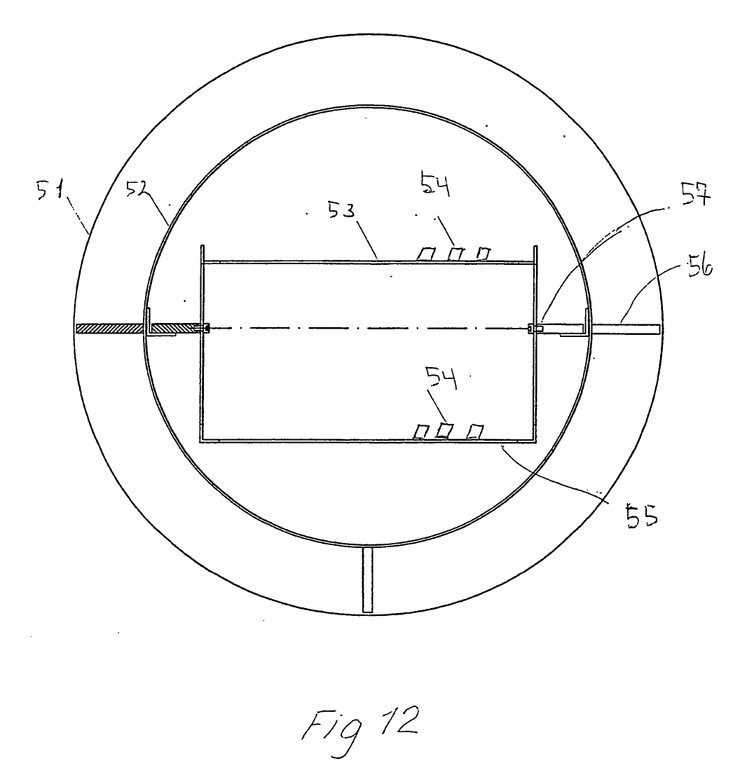

The voltage supply shown in FIG. 10, which is likewise intended to drive the apparatuses shown in FIGS. 2 and 3, utilizes one phase (r) from a three-phase network. One transformer is utilized for supplying the desired voltage to electrodes 1 and 2. Electrodes 1 and 2 are connected to the transformer so as to generate a varying voltage between electrode 1 and electrode 2 with the same frequency as phase (r).

The voltage supply shown in FIG. 11, which is intended to drive the apparatus shown in FIG. 4, utilizes all three phases (r, s, t) of the network. Three transformers are used for the electrodes 1, 2 and 3, respectively. The rear sides of the three transformers are connected to each other.

1. A method of exciting a plasma in a plasma treating chamber, wherein a gas is subjected to an electrical field generated by means of an electrode system comprising two or more electrodes, wherein a first outer electrode is formed as a pipe shaped electrode, said outer electrode surrounds an innermost pipe shaped electrode, which innermost electrode surrounds the plasma treating chamber, said method comprising the steps of introducing the gas into said plasma treating chamber and applying a power source to said electrodes to thereby generate a plasma in the plasma treating chamber.

2. A method according to claim 1, wherein the electrode system comprises two or more pipe shaped inner electrodes, at least one of said inner electrodes being the innermost electrode.

3. A method according to claim 2, wherein the innermost electrode is surrounded by the one or more additional inner electrode which in turn is surrounded by the outer electrode.

4. A method according to any one of the claims 1-3 wherein one or more of the pipe shaped electrodes comprising several through going openings in the pipe wall, said at least one pipe shaped electrode preferably being configured as a mesh.

5. A method according to any one of the claims 1-4 wherein at least one and preferably both of the outer electrode and the innermost electrode and optionally any additional inner electrodes having a substantially circular cross-section, said electrodes having a substantially circular cross-section preferably being substantially cylindrical in the whole pipe length of the electrode.

6. A method according to any one of the claims 1-4 wherein the outer electrode has a polygonal shape, preferably a rectangular shape, said outer electrode preferably surrounds two or more inner pipes, which more preferably having an elliptic shaped cross-section.

7. A method according to any one of the claims 1-6 wherein at least one of the electrodes are made of, or coated with a poorly conducting material, such as carbon-filled polyethylene.

8. A method according to any one of the claims 1-7 wherein the power source being selected from the group consisting of an alternating current (AC), a direct current (DC), low frequency (LF), audio frequency (AF), radio frequency (RF) and microwave power source.

9. A method according to any one of the claims 1-8 wherein the pressure in the plasma treating chamber being adjusted to less than 1 mbar, preferably to less than 0.4 mbar during the generation of plasma.

10. A method according to any one of the claims 1-9 further comprising the step of subjecting a substrate to a plasma treatment, said substrate being placed in the plasma treating chamber prior to the generation of the plasma.

11. An apparatus for excitation of a plasma, comprising a plasma treating chamber in which a gas may be subjected to an electrical field generated by means of an electrode system consisting of several electrodes, wherein a first outer electrode is formed as a pipe shaped electrode, said outer electrode surrounds an innermost pipe shaped electrode, which innermost electrode surrounds the plasma treating chamber.

12. An apparatus according to claim 11, said apparatus comprising an inlet for introducing the gas into the plasma treating chamber.

13. An apparatus according to any one of the claims 11 and 12 wherein the electrode system comprises two or more pipe shaped inner electrodes, at least one of said inner electrodes being the innermost electrode.

14. An apparatus according to claim 13 wherein the innermost electrode is surrounded by the one or more additional inner electrode which in turn is surrounded by the outer electrode.

15. An apparatus according to any one of the claims 11-14 wherein one or more of the pipe shaped electrodes comprising several through going openings in the pipe wall, said at least one pipe shaped electrode preferably being configured as a mesh.

16. An apparatus according to any one of the claims 11-15 wherein at least one and preferably both of the outer electrode and the innermost electrode and optionally any additional inner electrodes having a substantially circular cross-section, said electrodes having a substantially circular cross-section preferably being substantially cylindrical in the whole pipe length of the electrodes.

17. An apparatus according to any one of the claims 11-15 wherein the outer electrode has a polygonal shape, preferably a rectangular shape, said outer electrode preferably surrounds two or more inner pipes, which more preferably having an elliptic shaped cross-section.

18. An apparatus according to any one of the claims 11-17 wherein at least one of the electrodes are made of or coated with a poorly conducting material, such as carbon-filled polyethylene.

19. An apparatus according to any one of the claims 11-18 wherein the electrodes comprising means for being connected to a power source, preferably selected from the group consisting of an alternating current (AC), a direct current (DC), low frequency (LF), audio frequency (AF), radio frequency (RF) and microwave power source.

20. An apparatus according to any one of the claims 11-19 further comprising a vacuum pump for evacuating the plasma treating chamber.

21. An apparatus according to any one of the claims 11-20 further comprising a holder for holding a substrate to be plasma treated, said holder being placed in the plasma treating chamber.

22. An apparatus according to any one of the claims 11-21 further comprising a sputtering electrode, said sputtering electrode preferably being placed in the plasma treating chamber.

23. Use of an apparatus as defind in any one of the claims 11-22 for surface treating a substrate, wherein the substrate is placed in the plasma treating chamber of the appatatus and the plasma is generated.
